(19) United States
(12) Patent Application Publication
(10) Pub. No.: US 2015/0083204 A1
(43) Pub. Date: Mar. 26, 2015

(54) CELL ARRANGEMENT

(71) Applicant: Nanyang Technological University, Singapore (SG)

(72) Inventors: Soon Fatt Yoon, Singapore (SG); Kian Hua Tan, Singapore (SG); Wan Khai Loke, Singapore (SG); Satrio Wicaksono, Singapore (SG); Daosheng Li, Singapore (SG)

(21) Appl. No.: 14/396,369

(22) PCT Filed: Feb. 25, 2013
(86) PCT No.: PCT/SG2013/000075

§ 371 Date: Oct. 22, 2014

Related U.S. Application Data
(60) Provisional application No. 61/637,058, filed on Apr. 23, 2012.

(51) Int. Cl. H01L 31/0725; H01L 31/18; H01L 31/0735

(52) U.S. Cl. CPC H01L 31/0725; H01L 31/0735; H01L 31/184
USPC 136/255; 438/74

(57) ABSTRACT

A cell arrangement including a plurality of solar sub cells stacked above one another, wherein at least one solar sub cell of the plurality of solar sub cells comprises an alloy of gallium, nitrogen, arsenic and antimony.

### CROSS-REFERENCE TO RELATED APPLICATION

This application claims the benefit of priority of U.S. provisional application No. 61/637,058 filed Apr. 23, 2012, the contents of it being hereby incorporated by reference in its entirety for all purposes.

### TECHNICAL FIELD

Various aspects of this disclosure relate to cell arrangements, such as that in solar cells.

### BACKGROUND

III-V multi junction (MJ) photovoltaic (PV) cells have a niche application as the best technology available today for on-grid megawatt capacity photovoltaic power plants (from 0.1 MW to over 100 W) due to the high solar conversion efficiency arising from the direct bandgap property of these materials. Currently, the state-of-the-art production-scale MJ III-V PV cell has recorded solar conversion efficiency of up to 44% under concentrated solar radiation. This solar conversion efficiency value is the highest amongst other competing solar cell technologies by a considerable margin. Under 1000× solar concentration (1000 sun), a 1 cm² III-V MJ solar cell with 44% cell efficiency produces as much power as fourteen (14) 5″-diameter silicon solar cells. Recent breakthroughs in solar cell conversion efficiency have made III-V concentrated photovoltaic (CPV) technology more viable than ever for on-grid megawatt capacity power generation. Major CPV players have large installed manufacturing capacity and ability to scale with volume at rate of at least 600 MW/year.

The most common form of multi junction PV cell consists of three sub-cells, which is called a triple-junction solar cell. FIG. 1A shows the solar spectrum and photon absorption characteristics by different sub cells of GaInP, GaAs and Ge in a conventional multi-junction PV cell. FIG. 1B shows a schematic of how the conventional multi junction PV cell consisting GaInP, GaAs and Ge sub cells absorbs solar energy. The sub-cells made of direct bandgap semiconductors GaInP and GaAs are tuned to absorb the solar energy windows more than about 1.9 eV and from about 1.4 to about 1.9 eV, respectively. The bottom sub-cell made of germanium (Ge) is tuned to absorb photons with energy between about 0.7 eV to about 1.4 eV.

The solid line in FIG. 1A represents the power density of solar spectrum at different wavelengths. The filled region under the solid line represents the power density converted by the multi junction PV cell to electrical power. It can be seen that the conversion efficiency of multi-junction PV cell is poor at energy region of 1 eV. Photons passing through the GaAs layer have less than 1.42 eV. Some of these photons possess excess energies beyond the Ge bandgap (0.67 eV). These excess energies are lost in the form of heat during the energy conversion process.

### SUMMARY

Various aspects of this disclosure provide an improved solar cell that is able to address at least partially the abovementioned challenges.

In various embodiments, a cell arrangement including a plurality of solar sub cells stacked above one another, wherein at least one solar sub cell of the plurality of solar sub cells includes an alloy of gallium, nitrogen, arsenic and antimony.

In various embodiments, a method of forming a solar cell including stacking a plurality of solar sub cells above one another, wherein at least one solar sub cell of the plurality of solar sub cells includes an alloy of gallium, nitrogen, arsenic and antimony.

### BRIEF DESCRIPTION OF THE DRAWINGS

The invention will be better understood with reference to the detailed description when considered in conjunction with the non-limiting examples and the accompanying drawings, in which:

FIG. 1A shows the solar spectrum and photon absorption characteristics by different sub cells of GaInP, GaAs and Ge in a conventional multi-junction PV cell.

FIG. 1B shows a schematic of how the conventional multi-junction PV cell including or consisting GaInP, GaAs and Ge sub cells absorbs solar energy.

FIG. 2 shows a schematic of a solar cell including a (Si)Ge based sub cell (any one of Ge or SiGe) on a substrate, a GaNAsSb based sub cell on the (Si)Ge based sub cell, a Ga(In)As based sub cell (any one of GaAs or GaInAs) on the GaNAsSb based sub cell and a (Al)GaInP based sub cell (any one of GaInP or AlGaInP) on the Ga(In)As based sub cell according to various embodiments.

FIG. 3 shows a schematic of a solar cell including a GaNAsSb based sub cell on a substrate, a Ga(In)As based sub cell (any one of GaAs or GaInAs) on the GaNAsSb based sub cell and an (Al)GaInP based sub cell (any one of GaInP or AlGaInP) on the Ga(In)As based sub cell according to various embodiments.

FIG. 4 shows a schematic of a GaNAsSb based sub cell according to various embodiments.

FIG. 5 shows a graph illustrating the photo-current of the GaNAsSb sub cell in FIG. 4 measured under one sun AM1.5G spectral condition.

FIG. 6 shows a graph plotting the open circuit voltage V_{oc} of the GaNAsSb sub cell according to various embodiments in FIG. 4 against solar concentration.

FIG. 7 is a graph plotting the current density against the open circuit voltage V_{oc} of a conventional GaInP/GaAs dual junction solar cell and the GaInP/GaAs/GaNAsSb triple junction solar cell according to various embodiments in FIG. 3.

FIG. 8 is a graph plotting the open circuit voltage Vₒₙ against solar concentration of the GaInP/GaAs/GaNAsSb triple junction solar cell according to various embodiments in FIG. 3.

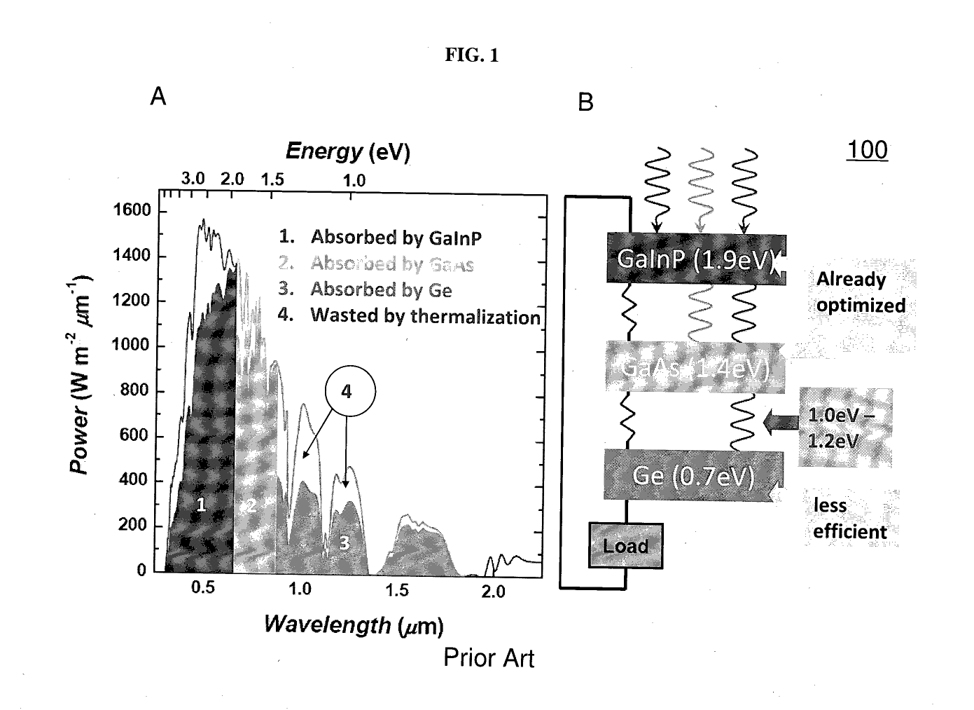

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

In order that the invention may be readily understood and put into practical effect, particular embodiments will now be described by way of examples and not limitations, and with reference to the figures.

In various embodiments, a cell arrangement including a plurality of solar sub cells stacked above one another, wherein at least one solar sub cell of the plurality of solar sub cells comprises an alloy of gallium (Ga), nitrogen (N), arsenic (As) and antimony (Sb). In various embodiments, the cell arrangement is a solar cell arrangement.

In other words, the solar cell arrangement may be a multi junction photovoltaic cell having more than one sub cell stacked on top one another.

The alloy of gallium, nitrogen, arsenic and antimony may offer flexibility for independent tuning of the conduction band offset by varying the nitrogen content, while the valence band offset can be tuned by varying the antimony content. This provides the ability to engineer the bandgap of GaNAsSb alloy. A solar cell having a GaNAsSb alloy based sub cell may be tuned to absorb photons having a particular range of energies, especially photons having the energies ranging between about 0.6 eV to about 1.4 eV or from about 0.9 eV to about 1.1 eV, therefore helping to address some of the abovementioned challenges.

A GaNAsSb based sub cell has advantages compared to other nitride based sub cells such as GaInNAs or GaInAs or GaInNAsSb. The amount of nitrogen-related defects in GaNAsSb may be lower due to the presence of antimony (Sb) atoms and the absence of indium (In) atoms during preparation. Antimony acts as a surfactant that improves incorporation efficiency of substitutional nitrogen (N) atoms and suppresses the formation of nitrogen-related defects. On the other hand, the incorporation of indium dilute nitride growth may lower the efficiency of nitrogen atom incorporation and promote the formation of nitrogen-related defects.

The material system of GaNAsSb alloy may also require fewer nitrogen atoms to achieve the desired bandgap compared to materials such as GaInNAs, thereby reducing the number of nitrogen related defects.

The improved substitutional incorporation properties may help to reduce the defect density in the GaNAsSb material. Any inefficiency in substitutional incorporation in the material may promote the formation of nitrogen-related defects, which may be detrimental to carrier lifetime and solar cell performance in general.

In various embodiments, the alloy may have a formula GaNₓAs_{1-x-y}Sb_{y}.

According to various embodiments, 0.01≦x≦0.04. According to various embodiments, 0.04≦y≦0.15.

In various embodiments, the cell arrangement is on a substrate. In various embodiments, the substrate may include a semiconductor material such as gallium arsenide, silicon, germanium, silicon germanium, graded silicon germanium. In various embodiments, the substrate may be a rigid substrate. In other alternative embodiments, the substrate may be a flexible substrate. In various embodiments, the cell arrangement may further include the substrate which is one of the plurality of solar sub cells.

In various embodiments, at least one of the solar sub cells may include a plurality of layers.

In various embodiments, the plurality of sub cells may be separated from one another by a tunnel junction layer. The tunnel junction may provide a low electrical resistance and optically low loss connection between two sub cells. Alternatively, the plurality of sub cells may be separated from one another by an intermediate layer.

In various embodiments, layers making up each solar sub-cell are matched in a substantially unstrained lattice to the substrate. In other words, each sub-cell may include a plurality of layers. The atoms of the element or elements in each layer form a lattice. The atomic spacing of the lattice in each layer is such that it matches to the lattice in a neighbouring layer such that both lattices in the two layers are not substantially strained. In this manner, the layers in a solar sub cells forms a substantially unstrained lattice and the layers between different sub-cells and the substrate also forms a substantially unstained lattice. The number of defects such as cracks in the lattice is thus minimized. In other words, by doing so, generation of defects due to lattice mismatch which in turn may degrade the performance of the solar cells, may be reduced.

In various embodiments, a solar sub cell nearer to the substrate is configured to absorb photons having a lower energy for converting into electrical energy than a solar sub cell further from the substrate.

The top sub cell may have the largest bandgap to ensure that only the most energetic photons are absorbed in this layer. Less energetic photons pass through the top sub cell since they are not energetic enough to generate electron-hole pairs in the material. Each sub cell going from the top to the bottom may have a smaller bandgap than the respectively above sub cell. Photons absorbed by a particular sub cell may have energies greater than the bandgap of the particular sub cell but have energies less than the bandgap of the sub cell above the particular sub cell. At least one sub cell in the cell arrangement may include an alloy of gallium, nitrogen, arsenic and antimony. In other words, at least one solar sub cell in the cell arrangement may have a layer including of an alloy of gallium, nitrogen, arsenic and antimony. There may be a solar sub cell above (the first adjacent sub cell) the GaNAsSb based sub cell. The first adjacent solar sub cell may have a corresponding layer having a bandgap larger than the bandgap of the alloy of GaNAsSb. There may be a solar sub cell (the second adjacent sub cell) below the sub cell having the GaNAsSb layer. The second adjacent sub cell may have a corresponding layer having a bandgap smaller than the bandgap of GaNAsSb.

In the current context, a first solar sub cell adjacent to a second solar sub cell refers to the first solar sub cell immediately next to the second solar sub cell or that the first solar sub cell is separated from the second solar sub cell by a tunnel junction layer or intermediate layer. In other words, no other solar sub cell is between the first solar sub cell and the second solar sub cells.

Previously, without the GaNAsSb-based sub cell, photons passing from the first adjacent sub cell to the second adjacent sub cell below the first adjacent sub cell will be absorbed by the second adjacent sub cell if the photons have a energy bigger than the band gap of the second adjacent sub cell. However, as the difference in energy band gap between the first adjacent sub cell and the second adjacent sub cell is large, the second adjacent sub cell may end up absorbing photons having energies much higher than the bandgap of the second adjacent sub cell but still lower than the bandgap of the first adjacent sub cell. These excess energies may be lost as heat. As the GaNAsSb-based sub cell may have an energy bandgap between that of the first adjacent sub cell and the second adjacent sub cell, it may be able to absorb some of these photons with energies higher than the bandgap of GaNAsSb, hence reducing some of the excess energies lost as heat.

In this manner, the efficiency of the solar cell may be improved. In other words, by providing the GaNAsSb-based sub cell, the difference between the absorbed photon energies for some of the photons is reduced, which in turns reduces the excess energy lost as heat.

A cell arrangement with a solar sub cell further from the substrate configured to absorb photons having a lower energy for converting into electrical energy than a solar sub cell nearer from the substrate may also be envisioned. The substrate may be optically transparent and may have an energy band gap wider than the sub cells. Photons passing through the substrates would mostly not be absorbed by the substrate, except for the most energetic ones. Photons passing though the sub cell adjacent to the substrate and having energies more than the energy band gap of the sub cell will be absorbed by the sub cell. Each sub cell going from the bottom (nearest to the substrate) to the top (furthest from the substrate) may have a smaller bandgap than the below sub cell.

In various embodiments, a first solar sub cell is arranged at the top surface of the cell arrangement, and the at least one solar sub cell including the alloy of gallium, nitrogen, arsenic and antimony is arranged below the first solar sub cell so that light is received by the first solar sub cell and a portion of the light passing through the first solar sub cell is received by the at least one solar sub cell including the alloy of gallium, nitrogen, arsenic and antimony. In various embodiments, the first solar sub cell may include (Al)GaInP. In other words, the first solar sub cell may include any one of aluminum gallium indium phosphide (AlGaInP) or gallium indium phosphide (GaInP). In various embodiments, one or more or solar sub cells may be arranged between the first solar sub cell and the solar sub cell including the alloy of gallium, nitrogen, arsenic and antimony. In various embodiments, the portion of the light passing through the first solar sub cell and received by the at least one solar sub cell including the alloy of gallium, nitrogen, arsenic and antimony may have an energy less than the energy bandgap of the first solar sub cell but equal or more than the energy bandgap of the at least one sub cell comprising the alloy of gallium, nitrogen, arsenic and antimony.

In various embodiments, a second solar sub cell may be arranged at the bottom of the cell arrangement; and wherein the at least one solar sub cell including the alloy of gallium, nitrogen, arsenic and antimony is arranged above the second solar sub cell so that light is received by the at least one solar sub cell including the alloy of gallium, nitrogen, arsenic and antimony and a portion of the light passing through the at least one solar sub cell including the alloy of gallium, nitrogen, arsenic and antimony is received by the second solar sub cell. In various embodiments, one or more solar cells may be arranged between the solar sub cell including the alloy of gallium, nitrogen, arsenic and antimony and the second solar sub cell. In various embodiments, the portion of the light passing through the at least one solar sub cell including the alloy of gallium, nitrogen, arsenic and antimony and received by the second solar sub cell may have energy less than the energy band gap of the at least one solar sub cell including the alloy of gallium, nitrogen, arsenic and antimony but equal or more then the energy bandgap of the second solar sub cell.

In various embodiments, the cell arrangement may further include a solar sub cell including gallium arsenide adjacent to the at least one solar sub cell comprising the alloy of gallium, nitrogen, arsenic and antimony.

In various embodiments, the cell arrangement may further include a solar sub cell including indium gallium arsenide adjacent to the at least one solar sub cell including the alloy of gallium, nitrogen, arsenic and antimony.

In various embodiments, the cell arrangement may further include a solar sub cell including germanium adjacent to the at least one solar sub cell including the alloy of gallium, nitrogen, arsenic and antimony.

According to various embodiments, the alloy may have an energy band gap ranging from about 0.6 eV to about 1.4 eV or from about 0.9 eV to about 1.1 eV. In other words, by adjusting the composition of the various elements making up the alloy GaNAsSb, the bandgap of the alloy GaNAsSb can be tuned to a value within the range from about 0.6 eV to about 1.4 eV or from about 0.9 eV to about 1.1 eV.

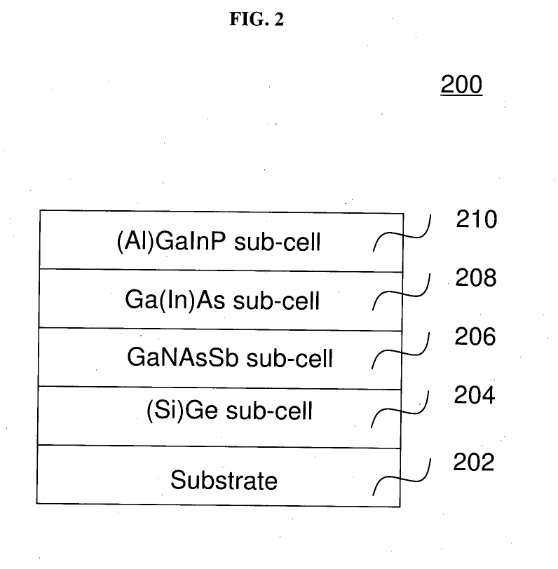

FIG. 2 shows a schematic of a solar cell 200 including a (Si)Ge-based sub cell 204 (any one of Ge or SiGe) on a substrate 202, a GaNAsSb based sub cell 206 on the (Si)Ge-based sub cell 204, a Ga(In)As based sub cell 208 (any one of GaAs or GaInAs) on the GaNAsSb based sub cell 206 and a (Al)GaInP sub cell 210 (any one of GaInP or AlGaInP) on the Ga(In)As-based sub cell 208 according to various embodiments. In various embodiments, there may be a sub cell 208 (the first adjacent sub cell) above the GaNAsSb based sub cell 206. The first adjacent sub cell may have a layer having a bandgap larger than the bandgap of GaNAsSb. The corresponding layer of the first adjacent sub cell 208 may include gallium indium arsenide (GaInAs). Gallium indium arsenide may have a bandgap ranging from about 1.0 eV to about 1.42 eV. The bandgap of gallium indium arsenide may vary with the concentration of indium. In various embodiments, the corresponding layer of the first adjacent sub cell 208 may include gallium arsenide (GaAs). The bandgap of gallium arsenide may be about 1.42 eV. There may be a sub cell (the second adjacent sub cell) 204 below the sub cell having the GaNAsSb layer 206. The second adjacent sub cell 204 may also have a corresponding layer having a bandgap smaller than the bandgap of GaNAsSb. The corresponding layer of the second adjacent sub cell may be silicon germanium (SiGe) having a bandgap ranging from about 0.67 eV to about 1.1 eV. The bandgap of SiGe may depend on the concentration of silicon. The corresponding layer of the second adjacent sub cell may be germanium. The bandgap of germanium may be about 0.67 eV. Photons passing out from the first adjacent sub cell 208 (i.e. the Ga(In)As based sub cell) to the GaNAsSb based sub cell 206 may have energies below about 1.42 eV. In the case of Ge, without the GaNAsSb based sub cell 206, photons having energies ranging from about 0.67 eV to about 1.42 eV may be absorbed by the second adjacent sub cell 204 (i.e. the Ge based sub cell). For photons having energies more than about 0.67 eV, the excess energies above about 0.67 eV may be lost as heat. By having the GaNAsSb based sub cell 206 positioned between the GaAs based sub cell 208 and the Ge based sub cell 204 and having the bandgap of the alloy GaNAsSb tuned to a value within the range from about 0.6 eV to about 1.4 eV or from about 0.9 eV to about 1.1 eV., the GaNAsSb based sub cell 206 is configured to absorb photons having energies more than the value. As such, some of the energies that would have been lost as heat without the GaNAsSb based sub cell 206 are now converted into kinetic and potential energies in the generated holes and electrons in the GaNAsSb based sub cell 206. By adjusting the compositions of the various elements in GaNAsSb, bandgap of GaNAsSb is tuned to a value within the range from about 0.6 eV to about 1.4 eV, or from about 0.9 eV to about 1.1 eV while allowing GaNAsSb to be lattice matched with the substrate 202 and the Ga(In)As and (Si)Ge. In order words, by varying the compositions of the various elements in GaNAsSb, efficiency of the solar cell 200 may be improved by providing a bandgap between that of Ga(In)As and (Si)Ge, and at the same time reduces generation of defects.

In addition, the corresponding layer of the sub cell on the first adjacent sub cell 210 may include (Al)GaInP. In various embodiments, the sub cell 210 on the first adjacent sub cell 208 may be configured to absorb photons having energies more than about 1.9 eV.

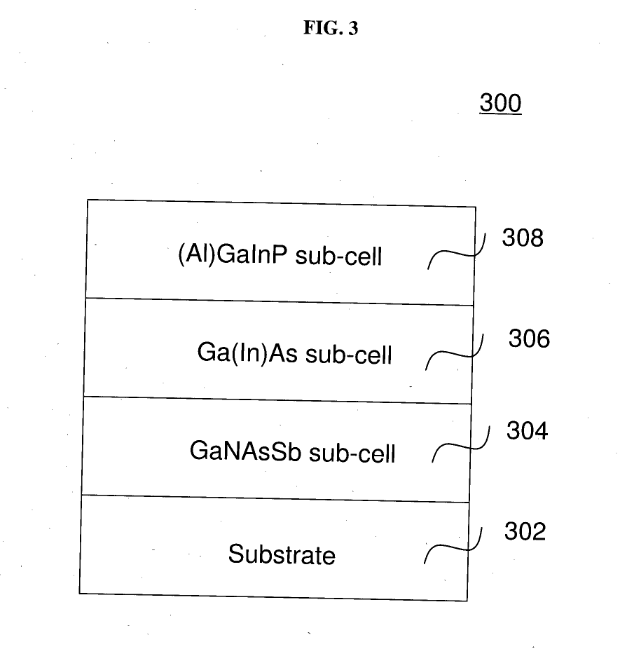

FIG. 3 shows a schematic of a solar cell 300 including a GaNAsSb based sub cell 304 on a substrate 302, a Ga(In)As based sub cell 306 (any one of GaAs or GaInAs) on the GaNAsSb based sub cell 304 and a (Al)GaInP based sub cell 308 (any one of GaInP or AlGaInP) on the Ga(In)As based sub cell 306 according to various embodiments. In various embodiments, there may be a sub cell 306 (the first adjacent sub cell) above the GaNAsSb based sub cell 304. The first adjacent sub cell 306 may have a first layer having a bandgap larger than the bandgap of GaNAsSb 304. The first layer of the first adjacent sub cell 306 may include gallium indium arsenide (GaInAs). GaInAs may have a bandgap ranging from about 1.0 eV to about 1.42 eV. The bandgap of gallium indium arsenide may vary with the concentration of indium. In various embodiments, the corresponding layer of the first adjacent sub cell 306 may include gallium arsenide (GaAs). The bandgap of gallium arsenide may be about 1.42 eV. In various embodiments, the GaNAsSb based sub cell 304 may be on a substrate 302. Photons passing from the first adjacent sub cell 306 (ie. the GaAs based sub cell) to the GaNAsSb based sub cell 304 will have energies below about 1.42 eV. Without the GaNAsSb based sub cell, photons having energies less than about 1.42 eV will either pass through the substrate 302 or be absorbed by the substrate 302 with subsequent loss of energies of the photons as heat. By having the GaNAsSb based sub cell 304 positioned between the GaAs based sub cell 306 and the substrate 302 and having the bandgap of the alloy GaNAsSb tuned to a value within the range from about 0.6 eV to about 1.4 eV or from about 0.9 eV to about 1.1 eV, the GaNAsSb based sub cell 306 is configured to absorb photons having energies more than the value. As such, some of the excess energies that would have been lost as heat without the GaNAsSb based sub cell 306 are now converted into electrical energies in the generated holes and electrons in the GaNAsSb based sub cell 304. By adjusting the compositions of the various elements in GaNAsSb, bandgap of GaNAsSb is tuned to a value within the range from about 0.6 eV to about 1.4 eV or from about 0.9 eV to about 1.1 eV while allowing GaNAsSb to be lattice matched with the substrate and the Ga(In)As. In order words, by varying the compositions of the various elements in GaNAsSb, efficiency of the solar cell 300 may be improved by providing a bandgap lower that of GaAs, and at the same time reduces generation of defects. In addition, the first layer of the sub cell 308 on the first adjacent sub cell 306 may include (Al)GaInP. In various embodiments, the sub cell 308 on the first adjacent sub cell 306 may be configured to absorb photons having energies more than 1.9 eV.

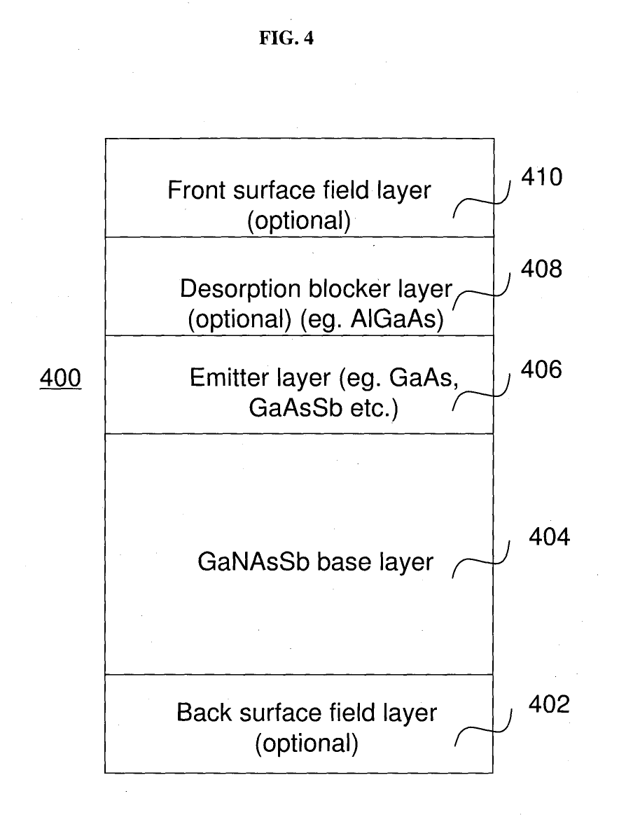

FIG. 4 shows a schematic of a GaNAsSb based sub cell 400 according to various embodiments. In various embodiments, the sub cell may include a first layer 404 and a second layer 406 on the first layer 404, wherein the first layer 404 (also referred to as the base layer) may include an alloy consisting of gallium, nitrogen, arsenic and antimony. The sub-cell 400 may be used in a multi junction solar cell. In various embodiments, an alloy including or consisting of gallium, nitrogen, arsenic and antimony is used in a sub cell of a solar cell or a solar cell.

The second layer 406 may also be referred to as the emitter layer. Generally, the second layer 406 may include any suitable material having a bandgap larger or equal than the alloy of GaNAsSb and a lattice constant similar to that of the alloy of GaNAsSb such that the first layer 404 and second layer 406 may be matched to form a substantially unstrained lattice. In various embodiments, the second layer 406 may include Ga(In)As and (Al)Ga(In)P. In various embodiments, the second layer 406 may include GaNAsSb. In other words, the second layer 406 may be of the same material as the first layer 404 or of different material.

Each sub cell, including the GaNAsSb sub cell, may further include a front surface field layer 410. The front surface field layer 410 may serve to reduce the surface recombination by reflecting minority carriers back towards the pn junction. Each sub cell, including the GaNAsSb sub cell, may further include a back surface field layer 402. The back surface field layer 402 may help to reduce the recombination of minority carriers by reflecting them back towards the pn junction. The front surface field layer 410 and the back surface field layer 402 may include GaAs or AlGaAs or GaInP or AlGaInP.

Each sub cell including the GaNAsSb sub cell, may also include a desorption blocker layer 408. The desorption blocker layer 408 may prevent surface damage during the high temperature in-situ annealing process.

In various embodiments, the first layer 404 may be doped with dopants of a first conductivity type and the second layer 406 is doped with dopants with a second conductivity type. In various embodiments, the optional back surface field layer 402 and the first layer 404 are doped with dopants of the first conductivity type while the optional front surface field layer 410, the optional desorption blocker layer 408 and the second layer 406 are doped with dopants of the second conductivity type.

In various embodiments, the first layer 404 is doped with n-type dopants such as silicon. In various embodiments, the second layer 406 is doped with p-type dopants such as beryllium, carbon or zinc. In various embodiments, the optional back surface field layer 402 and the first layer 404 are doped with n-type dopants such as silicon while the optional front surface field layer 410, the optional desorption blocker layer 408 and the second layer 406 are doped with p-type dopants such as beryllium, carbon or zinc.

Alternatively, in various embodiments, the first layer 404 may be doped with p-type dopants such as beryllium, carbon or zinc. In various embodiments, the second layer 406 is doped with n-type dopants such as silicon. In various embodiments, the optional back surface field layer 402 and the first layer 404 are doped with p-type dopants such as beryllium, carbon or zinc while the optional front surface field layer 410, the optional desorption blocker layer 408 and the second layer 406 are doped with n-type dopants such as silicon.

In various embodiments, the solar cell may further include a plurality of electrode. Each sub-cell may have a pair of electrodes leading to an external circuit.

The solar cell having the GaNAsSb sub cell may have a solar cell efficiency higher by at least 5% compared to a conventional solar cell without the GaNAsSb sub cell.

In various embodiments, a method of forming a solar cell including stacking a plurality of solar sub cells above one another, wherein at least one solar sub cell of the plurality of solar sub cells may include an alloy of gallium, nitrogen, arsenic and antimony.

In various embodiments, a layer of at least one sub cell of the plurality of sub cells includes an alloy comprising or consisting of gallium, nitrogen, arsenic and antimony is formed by growing epitaxial layers of GaAsSb and subjecting the epitaxial layers to exposure of nitrogen.

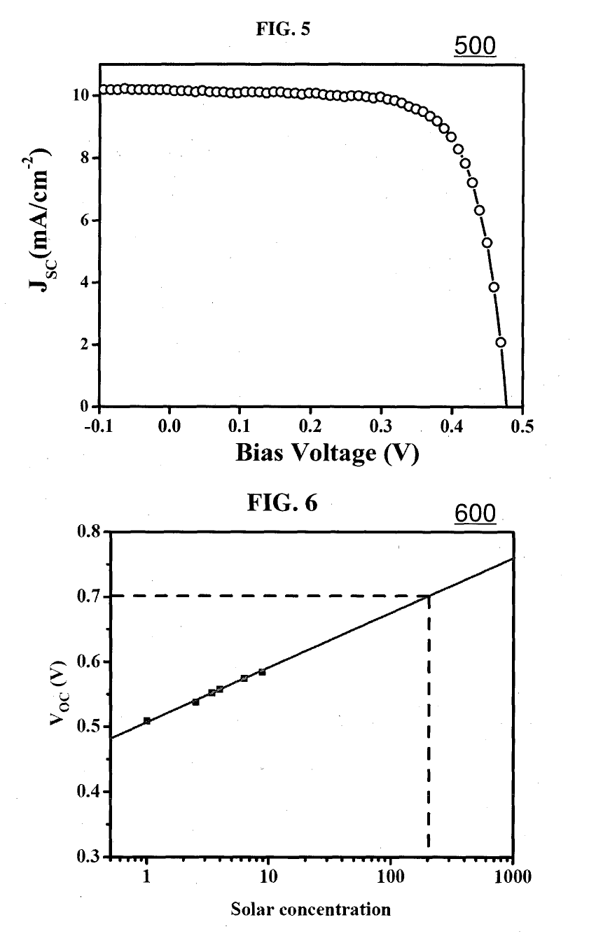

FIG. 5 shows a graph illustrating the photo-current of the GaNAsSb sub-cell in FIG. 4 measured under one sun AM1.5D spectral condition. The measurement was conducted using a 850 nm long pass filter that blocked photons with energy higher than the GaAs bandgap energy of 1.42 eV. This filter was selected so that the performance of the GaNAsSb material in the triple junction photovoltaic (PV) stack can be stimulated. It can be seen that the GaNAsSb sub cell is capable of delivering an open circuit voltage, Voc of 0.47V, short circuit current density, Jsc of 10.5 mN/cm² and fill factor of 72%. Moreover, the value of V_{oc} may be further increased by a higher solar concentration. Higher V_{oc} leads to higher energy conversion efficiency.

FIG. 6 shows a graph plotting the open circuit voltage V_{oc} of the GaNAsSb sub-cell according to various embodiments in FIG. 4 against solar concentration. It can be seen that the V_{oc} value of the GaNAsSb sub cell can reach 0.7V at about 200 sun concentration, making the GaNAsSb sub-cell suitable for CPV applications. FIG. 6 shows that the value of V_{oc} is increased by a higher solar concentration. Higher V_{oc} leads to higher energy conversion efficiency.

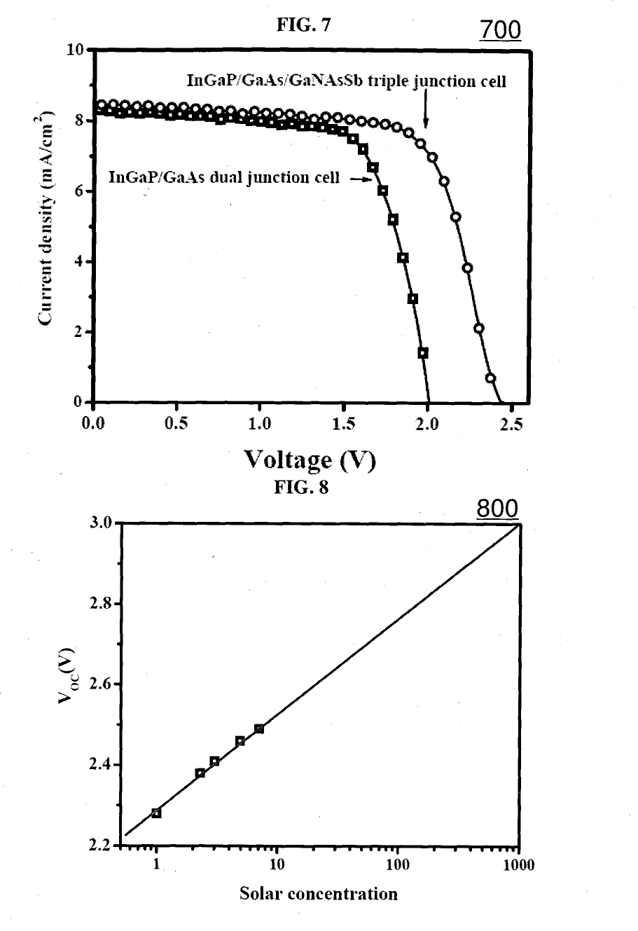

The GaNAsSb based sub cell has also been integrated into a multi junction (MJ) GaInP/GaAs photovoltaic cell. FIG. 7 is a graph plotting the current density against the open circuit voltage V_{oc} of a conventional GaInP/GaAs dual junction solar cell and a GaInP/GaAs/GaNAsSb triple junction solar cell according to various embodiments in FIG. 3. It can be seen that the incorporation of the GaNAsSb sub-cell improves the value of Voc by 0.4V, leading to higher energy conversion efficiency of the cell.

FIG. 8 is a graph plotting the open circuit voltage V_{oc} against solar concentration of a GaInP/GaAs/GaNAsSb triple junction solar cell according to various embodiments in FIG. 3. As shown in FIG. 8, by using a solar concentrator, the V_{oc} value of the GaInP/GaAs/GaNAsSb triple junction solar cell can be further increased to about 2.80V at a solar concentration of about 200.

For illustration purposes only and not as a limiting example, the term “substantially” may be quantified as a variance of +/−5% from the exact or actual. For example, the phrase “A is (at least) substantially the same as B” may encompass embodiments where A is exactly the same as B, or where A may be within a variance of +/−5%, for example of a value, of B, or vice versa.

In the context of various embodiments, the term “about” as applied to a numeric value encompasses the exact value and a variance of +/−5% of the value.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A cell arrangement comprising:
a plurality of solar sub cells stacked above one another; wherein a first solar sub cell of the plurality of solar sub cells comprises an alloy of gallium, nitrogen, arsenic and antimony.

2. The cell arrangement according to claim 1, wherein the alloy has a formula GaNₓAs_{1-x-y}Sb_{y}.

3. The cell arrangement according to claim 1, wherein the alloy has an energy band gap ranging from about 0.6 eV to about 1.4 eV.

4. The cell arrangement according to claim 1, wherein the plurality of solar sub cells are separated from one another by a tunnel junction layer.

5. The cell arrangement according to claim 2, wherein 0.01≦x≦0.04.

6. The cell arrangement according to claim 2, wherein 0.04≦y≦0.15.

7. The cell arrangement according to claim 1, wherein at least one of the solar sub cells comprises a plurality of layers.

8. The cell arrangement according to claim 1,
wherein a second solar sub cell is arranged at a top surface of the cell arrangement; and
wherein the first solar sub cell is arranged below the second solar sub cell so that light is received by the second solar sub cell and a portion of the light passing through the second solar sub cell is received by the first solar sub cell.

9. The cell arrangement according to claim 8, wherein the second solar sub cell comprises one of aluminum gallium indium phosphide and gallium indium phosphide.

10. The cell arrangement according to claim 1, further comprising:
a second solar sub cell comprising gallium arsenide adjacent to the first solar sub cell.

11. The cell arrangement according to claim 1 further comprising:
a second solar sub cell comprising indium gallium arsenide adjacent to the first solar sub cell.

12. The cell arrangement according to claim 1, wherein a second solar sub cell is arranged at the bottom of the cell arrangement; and
wherein the first solar sub cell is arranged above the second solar sub cell so that light is received by the first solar sub cell and a portion of the light passing through the first solar sub cell is received by the second solar sub cell.

13. The cell arrangement according to claim 1 further comprising:
a second solar sub cell comprising germanium adjacent to the first solar sub cell.

14. The cell arrangement according to claim 1, wherein each sub cell further comprises a back surface field layer.

15. The cell arrangement according to claim 1, wherein each sub cell further comprises a desorption blocker layer.

16. The cell arrangement according to claim 1, wherein each sub cell further comprises a front surface field layer.

17. The cell arrangement according to claim 1, wherein the first solar sub cell comprises:
a first layer of the alloy of gallium, nitrogen, arsenic and antimony; and
a second layer on the first layer.

18. The cell arrangement according to claim 17, wherein the second layer comprises gallium arsenide.

19. The cell arrangement according to claim 17, wherein the first layer is doped with dopants of a first conductivity type and the second layer is doped with dopants with a second conductivity type.

20. The cell arrangement according to claim 1, wherein the cell arrangement is on a substrate.

21. The cell arrangement according to claim 20, wherein layers making up each solar sub-cell are matched in a substantially unstrained lattice to the substrate.

22. The cell arrangement according to claim 20, wherein the substrate comprises of a semiconductor material.

23. The cell arrangement according to claim 22, wherein the semiconductor material is gallium arsenide.

24. The cell arrangement according to claim 20, wherein a solar sub cell nearer to the substrate is configured to absorb photons having a lower energy for converting into electrical energy than a solar sub cell further from the substrate.

25. The cell arrangement according to claim 20, wherein a solar sub cell further from the substrate is configured to absorb photons having a lower energy for converting into electrical energy than a solar sub cell nearer from the substrate.

26. A method of fabricating a cell arrangement, the method comprising:
stacking a plurality of solar sub cells above one another; wherein at least one solar sub cell of the plurality of solar sub cells comprises an alloy of gallium, nitrogen, arsenic and antimony.
